(19) United States
(12) Patent Application Publication
(10) Pub. No.: US 2006/0245165 A1
(43) Pub. Date: Nov. 2, 2006

(54) Elastic secure device of a heat radiation module

(76) Inventor: Fang-Cheng Lin, Taipei (TW)

Correspondence Address: G. LINK Co., LTD., 3550 Bell Road, MINOOKA, IL, 60447, US

(21) Appl. No.: 11/117,004

(22) Filed: Apr. 29, 2005

(51) Int. Cl. H05K 7/20

(52) U.S. Cl. 361/704

(57) ABSTRACT

An elastic secure device of a heat radiation module includes a back plate, a radiator, sleeves and joining elements. The back plate provides posts on a surface thereof. The radiator has a base with fins and through holes corresponding to the posts. The sleeves correspond to and are inserted into the through holes with each of the sleeves having an open end and a closed end. The open end has a flange contacting the surface of the base and the closed end has a hole being penetrated with the posts. The joining element is disposed in the respective sleeve, fixedly joined in the respective post and surrounded with an elastic element respectively. The elastic element biases against both the joining element and the respective sleeve respectively.

### BACKGROUND OF THE INVENTION

1. Field of the Invention

The present invention is related to an elastic secure device of a heat radiation module and particularly to an elastic joining device used for a radiator.

2. Brief Description of the Related Art

An ordinary electronic component such as the central processing unit creates a great deal of heat during normal operation and accumulated heat results in high temperature to seriously affect the normal operation of the electronic component unless the heat is removed properly. In order to remove the heat effectively, usually a radiator is fixedly attached to the electronic component

Currently, a popular way for attaching the radiator to the electronic component tightly is that a plurality of engaging elements penetrate through holes, which are provided in the radiator and the circuit board respectively, and are fastened at opposite side of the circuit board.

Referring to FIGS. 1 to 4, the conventional device includes a radiator 11, a back plate 12, a circuit board 13, a plurality of joining elements 14 and a plurality of springs 15. The radiator 11 has a base 111 with a plurality of fins 112 at the upper side thereof. The base 111 has a bottom side with completely smooth surface and a plurality of through holes 113.

The back plate 12 has a plurality of through holes 121 corresponding to through holes 113 in the base 111.

The circuit board 13 is preset with a central processing unit 131 and has a plurality of through holes 132.

Each of the joining elements 14 has a head part 141 and a post 142 connecting with the head part 141. The post 142 is provided with a screw fastening part 143 and each of the elastic elements surrounds the post 142.

When the conventional device is set up, the bottom side of the base 111 is closely attached to the surface of the central processing unit 31 and the back plate 12 is disposed at another side of the circuit board 13 opposite to the central processing unit 31. The through holes 113 of the base 111, the through holes 121 of the back plate 12 and the through holes 132 of the circuit board 13 correspond to one another for the post 142 of each joining element 14 passing through and the screw fastening part 143 engages with the respective through hole 121 of the back plate 12. Each of the elastic elements 15 presses against the head part 141 and the base 111 respectively. Hence, the bottom of the radiator 11 can be closely attached to the surface of the radiator 11 without moving randomly due to the radiator 11, the circuit board 13 and the back plate 12 being joined together so that the radiator is capable of performing heat dissipation.

However, the preceding prior art has a problem in practice. Although each of the elastic elements 15 presses against the head part 141 of the joining element 14 and the bottom side of the radiator 11 in order to prevent excessive force exerted by the joining element 14 from damage of the circuit board 13, the damage still occurs during actual operation because the back plate 12 squeezes toward the backside of the circuit board 13 to cause deformation or, more seriously, become rupture.

Further, referring to FIG. 5, the support side of the fins 112 is attached with a fan 16 and fluid induced by the fan 16 blows toward the radiator 11 to assist cooling the central processing unit 31 by means of heat exchange. When the fluid passes through gaps between the fins and moves backward, the head part 141 and the post of each joining element 14 extend outward the surface of the base 111 to hinder and interfere the fluid flow such that resistance of the fluid flow increases to reduce effect of heat dissipation.

### SUMMARY OF THE INVENTION

An object of the present invention is to provide an elastic secure device of a heat radiation module, which is capable of reducing resistance of fluid flow passing through the radiator.

In order to achieve the preceding object, the elastic secure device of the heat radiation module according to the present invention includes a back plate, a radiator, sleeves and joining elements. The back plate provides posts on a surface thereof. The radiator has a base with fins and through holes corresponding to the posts. The sleeves correspond to and are inserted into the through holes with each of the sleeves having an open end and a closed end. The open end has a flange contacting the surface of the base and the closed end has a hole being penetrated with the posts. The joining element is disposed in the respective sleeve, fixedly joined in the respective post and surrounded with an elastic element respectively. The elastic element biases against both the joining element and the respective sleeve respectively.

### BRIEF DESCRIPTION OF THE DRAWINGS

The detail structure, the applied principle, the function and the effectiveness of the present invention can be more fully understood with reference to the following description and accompanying drawings, in which:

FIG. 1 is an exploded perspective view of the conventional secure device with a heat radiation module;

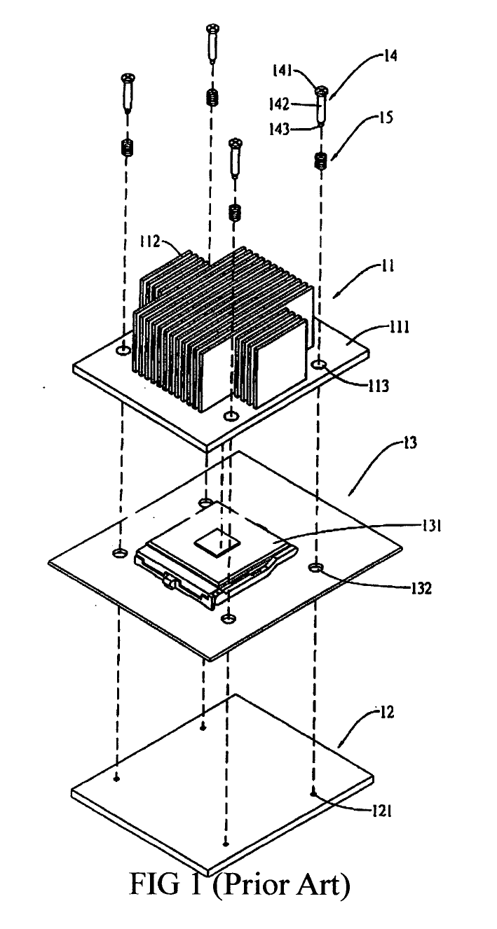

FIG. 2 is a fragmentary sectional view illustrating the secure device shown in FIG. 1 in a state of being detached;

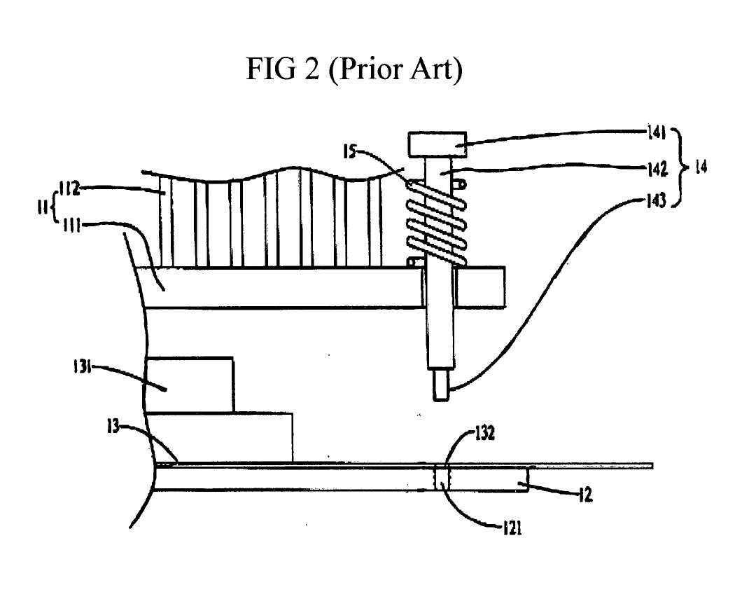

FIG. 3 is a perspective view illustrating the conventional secure device with a heat radiation module shown in FIG. 1 in a state of being assembled;

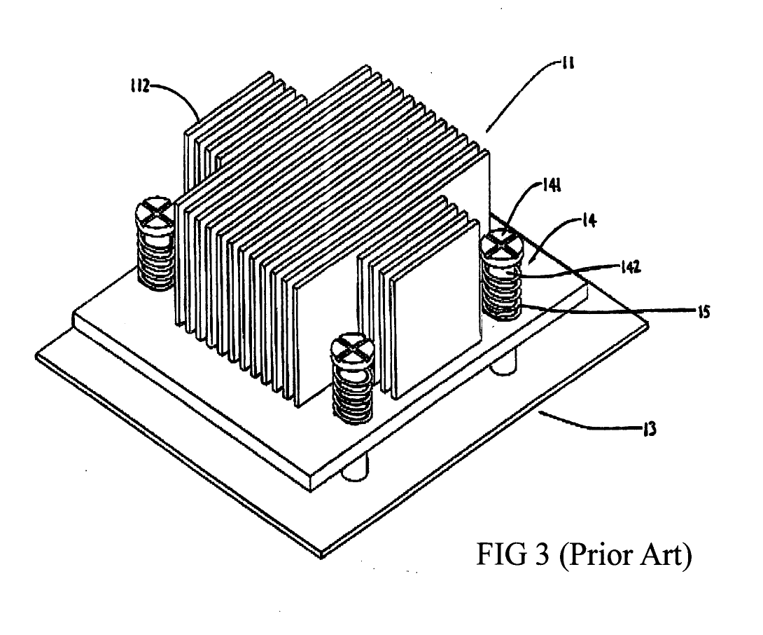

FIG. 4 is a fragmentary sectional view illustrating the secure device shown in FIG. 1 in a state of being attached;

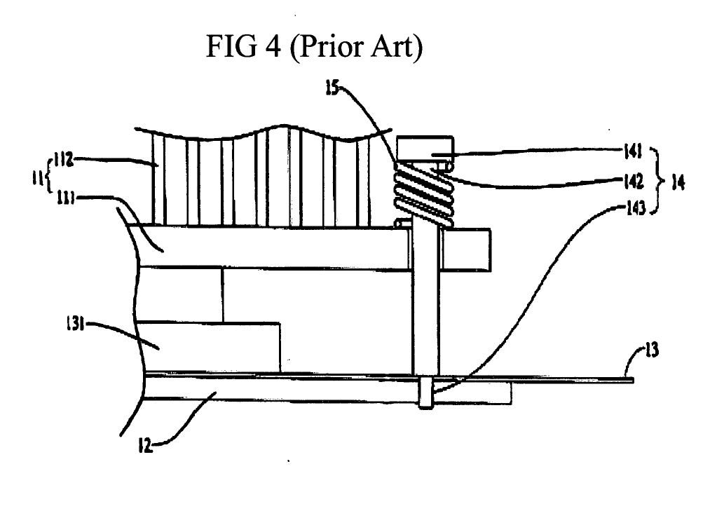

FIG. 5 is a sectional view illustrating the conventional secure device being mounted to a fan;

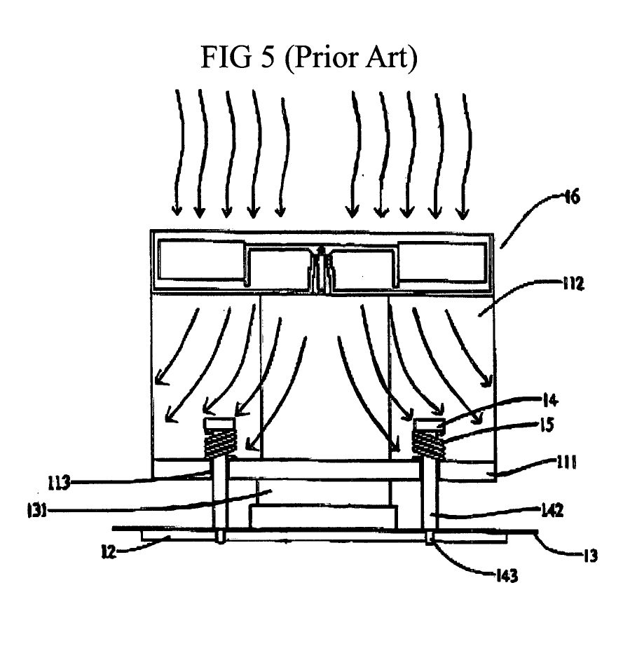

FIG. 6 is an exploded perspective view of an elastic secure device of a heat radiation module according to the present invention;

FIG. 7 is a fragmentary sectional view illustrating the secure device of the present invention in a state of being detached;

FIG. 8 is a perspective view of the elastic secure device of a heat radiation module according to the present invention;

FIG. 9 is a fragmentary sectional view illustrating the elastic secure device of the present invention in a state of being attached; and

FIG. 10 is a plan view illustrating the elastic secure device of the present invention mounted to a fan.

### DETAILED DESCRIPTION OF THE INVENTION

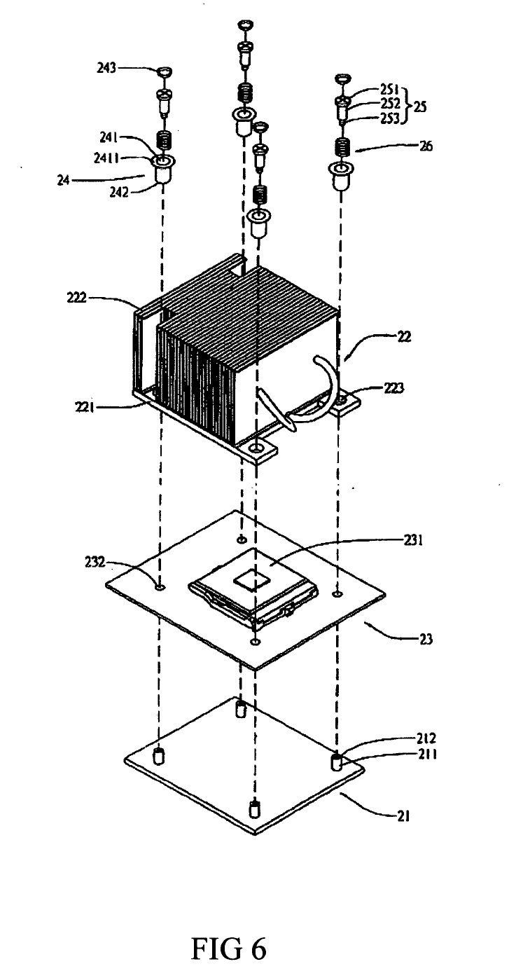

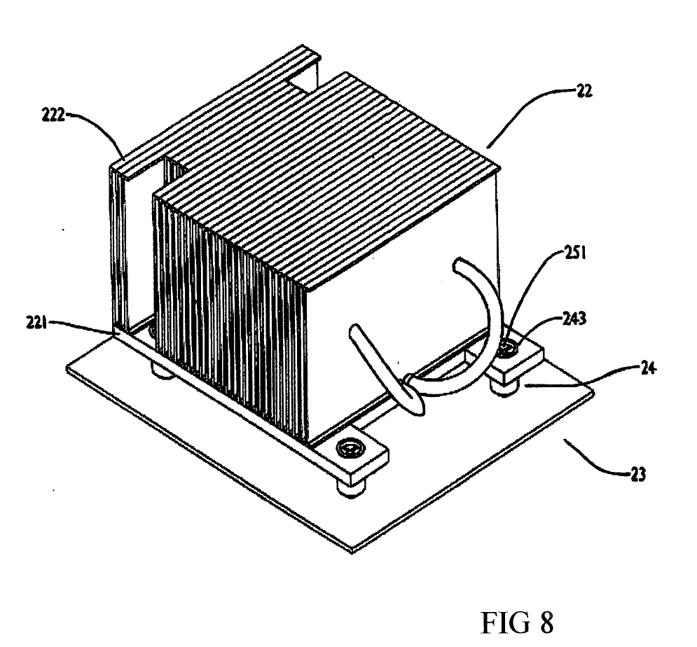

Referring to FIGS. 6 to 9, the preferred embodiment of an elastic secure device of a heat radiation module according to the present invention includes a back plate 21, a radiator 22, a flat member 23, at least a sleeve 24 and at least a joining element 25. The back plate 21 has a plurality of posts 211 thereon and each of the posts 211 has a hollow receiving part 212.

The radiator 22 is made of gold, silver, copper or aluminum and provides a base 221 with a plurality of upright fins 222 at a side thereof and has a smooth surface at another side thereof. There is at least a through hole 223 in the base 221 corresponding to the respective post 211 of the back plate 21.

The flat member 23, which is a circuit board in the embodiment, is attached with at least a heat generation component 231 and provides at least a through hole 232. The through hole 232 corresponds to the respective post 211 and the through hole 223 of the radiator 22.

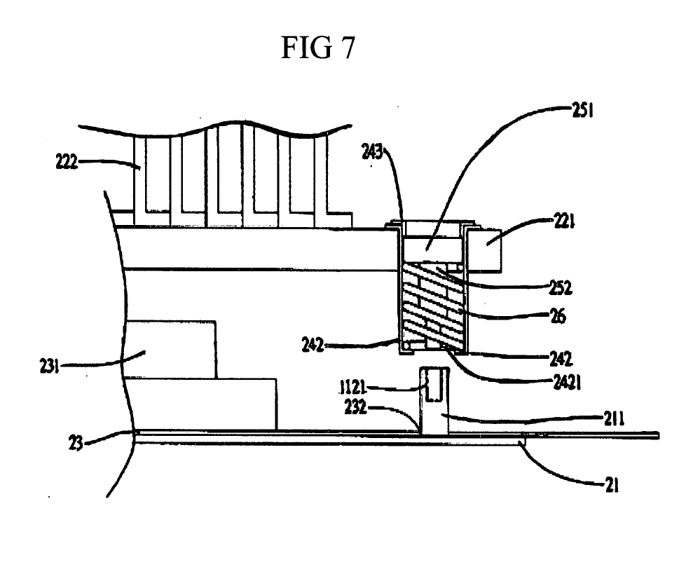

The sleeve 24, which is inserted into the through hole 223, has an open end 241 and a closed end 242. The open end 241 has a flange 2411 to contact the surface of the base 221 while the sleeve 24 is inserted into the through hole 223. The closed end 242 has a hole 2421 (shown in FIG. 7) for being penetrated by the respective post 211 of the back plate 21.

The joining element 25 is disposed inside the sleeve 24 with a head part 251 and an elongated section 252 extending from the heat part 251. A fixing part 253 is provided at the front end of the elongated section 252 and engaged in the receiving part 212 of the post 211. An elastic element 26 is disposed pressingly between the head 251 and closed end of the sleeve 24.

Further, the open end 241 of the sleeve 24 has an annular shaped fastening component 243 being fixedly attached to the periphery of the open end 241 to prevent the joining element from detaching from the sleeve 24. The receiving part 212 of the post 211 has internal screw threads 2121 to engage with external screw threads 2581 provided on the joining element 253.

The joining element is a screw in the embodiment but it is not a limitation and it can be substituted by other equivalent components in the scope of the present invention.

When the elastic secure device of a heat radiation module according to the present invention is set up, the side with smooth surface of the radiator 22 is closely contacts the heat generation part 231 preset on the flat member 23 and the back plate 21 is mounted to the flat member 23 from the side opposite to the heat generation part 231 with the post 211 passing through the through hole 232 of the flat member 23 and the hole 2421 in the closed end 242 of the sleeve 24 to allow the internal screw threads 2121 in the receiving part 212 engaging with the external screw threads 2531 of fixing part 253 at the front end of the joining element 25. In this way, the radiator 22 is capable of fixedly attached to the heat generation part 231 on the flat member 23 and the entire joining element 25 is capable of hiding in the through hole 223 provided in the base 221 of the radiator 22 without exposing outside the base 221.

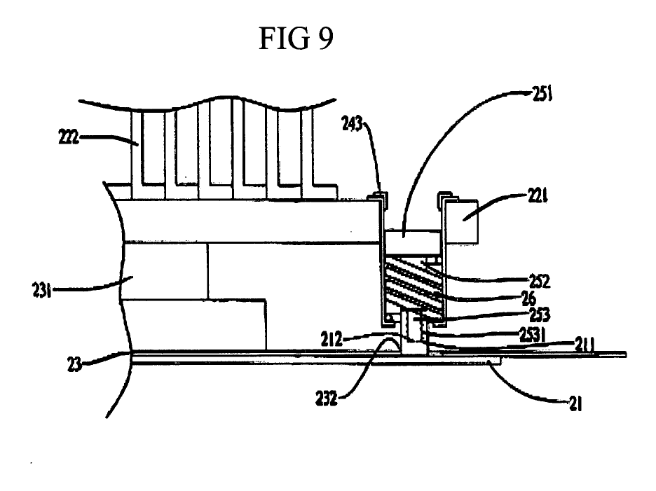

Normally, the elastic element 26 is in a state of extension as shown in FIG. 7 and when the fixing part 253 engages with the receiving part 212, the elastic element 26 is pressed by the head 251 of the joining element 25 and becomes a state of being compressed as shown in FIG. 9. Under this circumference, the elastic element 26 offers a resilient force to keep the radiator 22 contacting the heat generation part 231 tightly and no clearance is between the radiator 22 and the heat generation part 231 such that heat transfer efficiency of the heat generation part 231 can be promoted and heat dissipation effect can be enhanced greatly. Further, due to the elastic element 26 offering proper resilient force, excessive force exertion of the joining element 25 can be avoided and due to the fixing part 253 at the front end of the joining element 25 engaging with the receiving part 212 in the post 211 of the back plate 21, engaging force exerts to the back plate 21 directly to results in the back plate 21 being squeezed toward the flat member 23 excessively can be avoided to prevent the flat member 23 from being deformed or damaged.

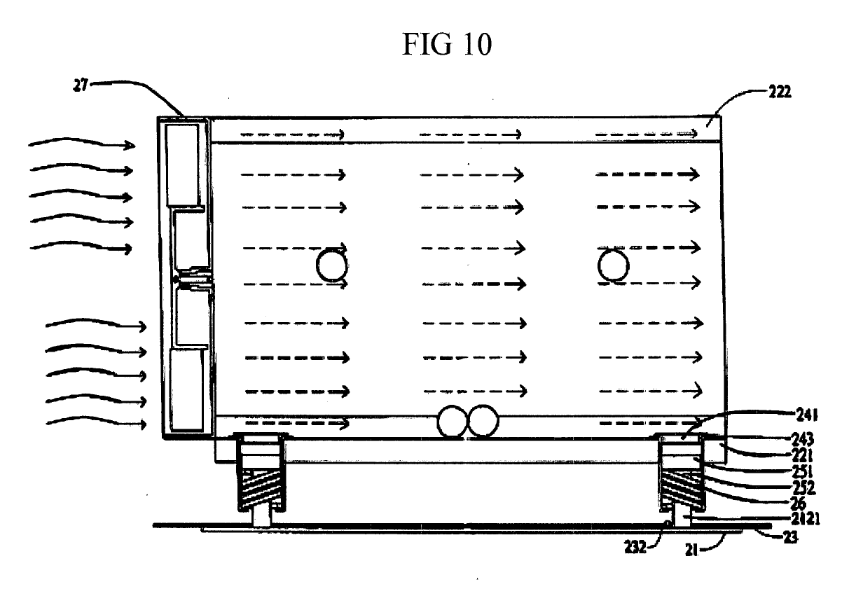

Referring to FIG. 10 in company with FIG. 6, in case of a fan 27 being attached to a support side of the radiator 22, the fan 27 is driven to induce fluid moving toward the radiator 22, the fluid can pass through spacing gaps between the fins 222 of the radiator 22 smoothly without any obstacles of exposing joining element 25 and heat exchange between the fins 222 and the fluid can be carried out fast to promote the overall heat dissipation effect. In this way, deficiency of being blocked by the exposing joining element, which resides in the conventional joining element of the radiator, can be overcome completely.

While the invention has been described with referencing to preferred embodiments thereof, it is to be understood that modifications or variations may be easily made without departing from the spirit of this invention, which is defined by the appended claims.

What is claimed is:

1. An elastic secure device of a heat radiation module, comprising:
a back plate, providing a plurality of post on a surface thereof;
a radiator, having a base with a plurality of upright fins and a plurality of through holes corresponding to the posts;
a plurality of sleeves, corresponding to and being inserted into the through holes, each of the sleeves having an open end and a closed end with the open end having a flange contacting the surface of the base and the closed end having a hole being penetrated with the posts;
a joining element, being disposed in the respective sleeve, fixedly joined in the respective post and being surrounded with an elastic element, which biases against the joining element and the respective sleeve.

2. The elastic secure device of a heat radiation module as defined in claim 1, wherein each of the posts has a hollow receiving section and the joining element has a head part and an elongated part with the elongated section having a fixing part engaging with the receiving part.

3. The elastic secure device of a heat radiation module as defined in claim 2, wherein the fixing part has external screw threads and the receiving part has internal screw threads so that the fixing part engages with the receiving part by way of the external screw threads joined to the internal screw threads.

4. The elastic secure device of a heat radiation module as defined in claim 1, wherein the joining element is a screw.

5. The elastic secure device of a heat radiation module as defined in claim 1, wherein the elastic element is a spring.

6. The elastic secure device of a heat radiation module as defined in claim 1, wherein the base provides a flat side without the fins.

7. The elastic secure device of a heat radiation module as defined in claim 1, wherein the open end of the sleeve has an annular shaped fastening component being fixedly attached to the periphery of the open end.

8. The elastic secure device of a heat radiation module as defined in claim 1, wherein the flat member is a circuit board attached with a heat generation part and has a plurality of fixing holes corresponding to the post.

9. The elastic secure device of a heat radiation module as defined in claim 1, wherein the radiator is made of good conductive material.

10. The elastic secure device of a heat radiation module as defined in claim 9 is made of gold, silver, aluminum or copper.
